(19) United States
(12) Patent Application Publication
(10) Pub. No.: US 2014/0291942 A1
(43) Pub. Date: Oct. 2, 2014

(54) CHUCK STRUCTURE FOR SUBSTRATE CLEANSING EQUIPMENT

(71) Applicant: GUDENG PRECISION INDUSTRIAL CO., LTD., New Taipei City 236 (TW)

(72) Inventors: AN-PANG WANG, NEW TAIPEI CITY (TW); YUNG-CHIN PAN, NEW TAIPEI CITY (TW); SHENG-HSIEN YU, NEW TAIPEI CITY (TW); TSUNG YI YANG, NANTOU COUNTY (TW)

(73) Assignee: GUDENG PRECISION INDUSTRIAL CO., LTD., NEW TAIPEI CITY (TW)

(21) Appl. No.: 13/889,548

(22) Filed: May 8, 2013

(30) Foreign Application Priority Data
Mar. 27, 2013 (TW) 102205633

(51) Int. Cl. H01L 21/687

(52) U.S. Cl. CPC H01L 21/687; H01L 2221/683
USPC 279/142

(57) ABSTRACT

The present invention provides a chuck structure for substrate cleansing equipment, which comprises a base and at least a pair of clipping members. The pair of clipping members is disposed on both corresponding sides of the base, respectively. Each clipping member has a plurality of holes on a surface thereof. When the pair of clipping members moves towards the base, it clips a substrate such as a photomask, a wafer, or other semiconductor substrate. The surfaces of the clipping members having the plurality of holes are against the substrate for reducing the contact area between the clipping members and the substrate. Thereby, the static charges generated on the substrate by the friction between the clipping members and the substrate can be avoided, which can reduce the damages on the substrate due to electrostatic discharge effectively.

### FIELD OF THE INVENTION

The present invention relates generally to a chuck structure, and particularly to a chuck structure capable of reducing residual static charges on a substrate.

### BACKGROUND OF THE INVENTION

Currently, during the fabrication process, the delicate and valuable substrates, including wafers for fabricating semiconductor devices, magnetic storage disc substrates, and LCD panel substrates, need to be transported continuously for various process steps. Nonetheless, these kinds of substrates are vulnerable to damages caused by environmental influences such as dust, electrostatic discharge, vibration, and gaseous containment.

Dust and the pollutants in the form of particles coming from the atmosphere will adhere to the substrates and cause irreversible damages. Because the size of integrated circuits is kept shrinking, the size of the particles threatening integrated circuits becomes smaller. Thereby, minimizing the pollutants has become extremely important. In the semiconductor industry, complicated methods, such as clean rooms, are adopted for preventing the environmental influences on the substrates.

While cleaning a substrate, the cleaning equipment usually has a chuck structure for clipping the substrate and cleaning. If the contact area between the chuck structure and the substrate is large, friction tends to happen therebetween, which may lead to a large number of static charges. When a large number of static charges are residual on the substrate, electrostatic discharge tends to happen and destroys the patterns on the substrate. Thereby, the accuracy of the pattern on the substrate is reduced, affecting the precision of subsequent processes.

Accordingly, the present invention provides a chuck structure for substrate cleansing equipment, which can reduce the contact area between the chuck structure and the substrate for reducing the friction therebetween. Thereby, the quantity of the static charges on the substrate generated by friction is lowered and thus avoiding damages on the substrate due to electrostatic discharge.

### SUMMARY

An objective of the present invention is to provide a chuck structure for substrate cleansing equipment, which reduces the contact area between the chuck structure and the substrate for reducing the friction therebetween. Thereby, the quantity of the static charges on the substrate generated by friction is lowered and thus avoiding damages in the substrate due to electrostatic discharge.

For achieving the objective described above, the present invention discloses a chuck structure for substrate cleansing equipment, which comprises a base and at least a pair of clipping members disposed on both opposing sides of the base. Each clipping member has a plurality of holes on a surface thereof. The pair of clipping members clips a substrate. The surfaces having the plurality of holes are against the substrate.

### BRIEF DESCRIPTION OF THE DRAWINGS

FIG. 1 shows a schematic diagram of the chuck structure according to the first embodiment of the present invention;

FIG. 2A shows a usage diagram of the chuck structure according to the first embodiment of the present invention;

FIG. 2B shows another usage diagram of the chuck structure according to the first embodiment of the present invention;

FIG. 3 shows a schematic diagram of the clipping member according to the first embodiment of the present invention;

FIG. 4 shows a cross-sectional of the clipping member according to the second embodiment of the present invention;

FIG. 5 shows a usage diagram of the chuck structure according to the second embodiment of the present invention;

FIG. 6 shows a schematic diagram of the chuck structure according to the third embodiment of the present invention; and

FIG. 7 shows a usage diagram of the chuck structure according to the third embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The chuck structure according to the prior art clips a substrate such as a photomask, a wafer, or other semiconductor substrate. When the chuck structure comes off the substrate, friction occurs. Owing to the friction between the substrate and the chuck structure, a great number of static charges are generated and residual on the substrate. The residual static charges on the substrate can induce electrostatic discharge and further damage the patterns on the substrate, which leads to reduction in the precision for subsequent processes. Accordingly, the present invention provides a chuck structure for substrate cleansing equipment, which reduces the contact area between the chuck structure and the substrate and thus reducing the area of friction on the substrate. Thereby, the friction between the chuck structure and the substrate when the chuck structure comes off the substrate is reduced. A great number of residual static charges can be prevented and hence avoiding damages on the substrate due to electrostatic discharge.

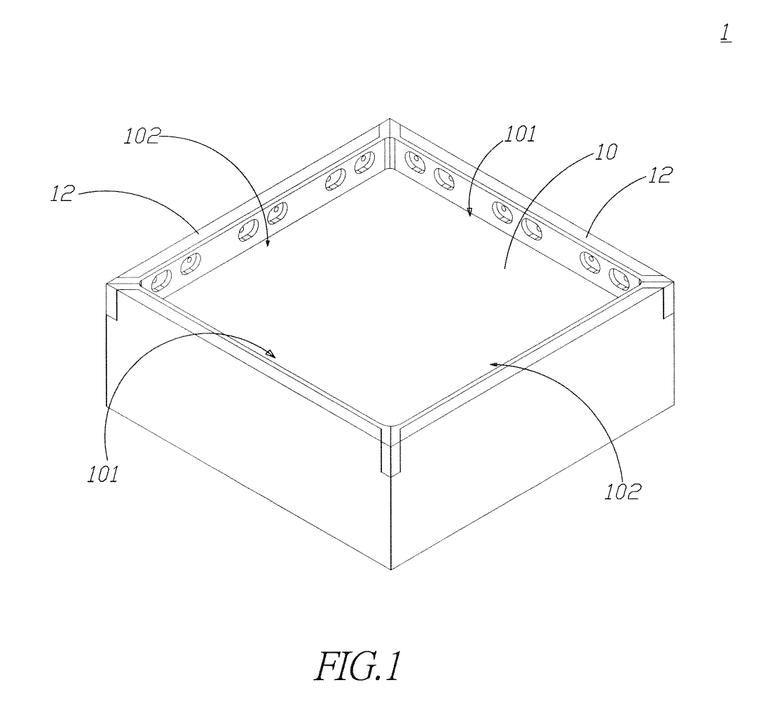

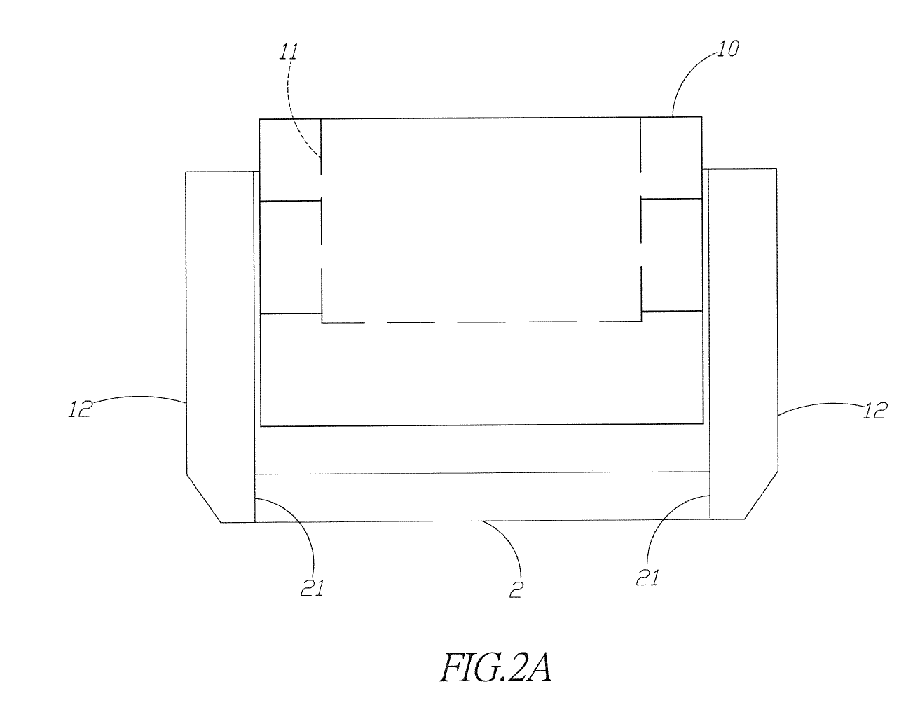

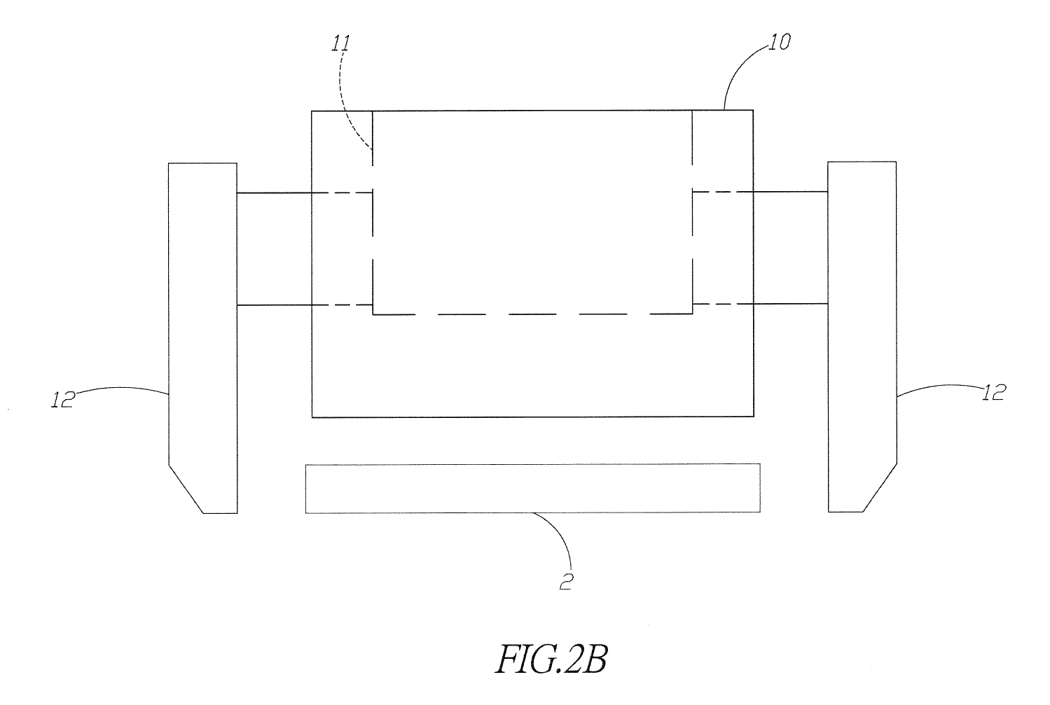

FIG. 1 and FIG. 2A shows a schematic diagram and a usage diagram of the chuck structure according to the first embodiment of the present invention. As shown in the figure, the present embodiment provides a chuck structure 1 for substrate cleansing equipment, which comprises a conductive base 10 and two pairs of clipping members 12. The conductive base 10 has two opposite first sides 101 and two opposite second sides 102. The two pairs of clipping members 12 are disposed on the two first sides 101 and the two second sides 102, respectively. The conductive base 10 has a driving device 11 therein. The driving device 11 is connected with the plurality of clipping members 12 for driving to move in the direction away from or close to the conductive base 10 simultaneously. According to the present embodiment, two pairs of clipping members 12 are disposed. Alternatively, only one pair of clipping member 12 can be disposed as well. The details will not be described again.

FIG. 2B shows another usage diagram of the chuck structure according to the first embodiment of the present invention. As shown in the figure, when the chuck structure 1 according to the present embodiment clips a substrate 2, the driving device 11 first drives the plurality of clipping members 12 to move in the direction away from the conductive base 10 simultaneously. Then the substrate 2 is disposed between the plurality of clipping members 12. The driving device 11 drives the plurality of clipping members 12 to move in the direction close to the conductive base 10 simultaneously. The plurality of clipping members 12 are against one side 21 of the substrate 2, respectively, for clipping the substrate 2, as shown in FIG. 2A.

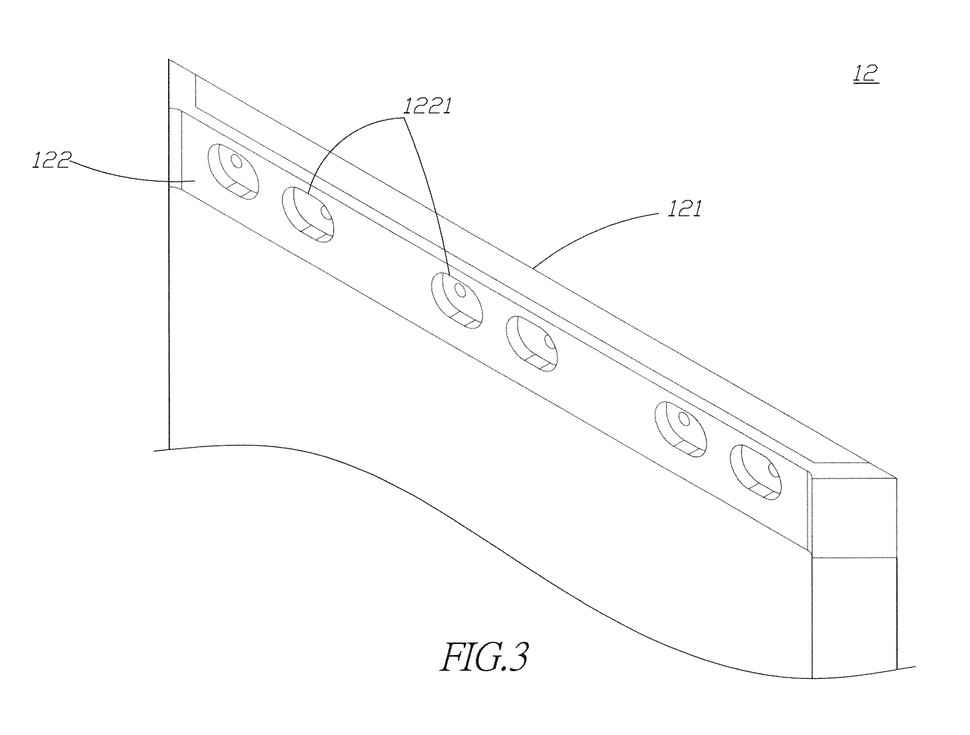

FIG. 3 shows a schematic diagram of the clipping member according to the first embodiment of the present invention. As shown in the figure, the clipping member 12 comprises a conductive base 121 and a rubber strip 122. The rubber strip 122 has a plurality of holes 1221; the plurality of holes 1221 penetrate the rubber strip 122. The rubber strip is disposed at the conductive base 121. The plurality of holes 1221 expose a portion of the conductive base 121. When the clipping member 12 is disposed at the conductive base 10, the rubber strip 122 faces the inside of the conductive base 10, as shown in FIG. 1, to make the surface of the rubber strip 122 having the plurality of holes 1221 against the side 21 of the substrate 2. Thereby, the contact area, and thus the area of friction, between the substrate 2 and the rubber strip 122 are reduced. When the clipping member 12 comes of the substrate 2, the friction caused by the substrate 2 peeling off the rubber strip 122 is lowered. Hence, the quantity of the static charges generated by the friction between the substrate 2 and the rubber strip 122 is reduced; a great number of residual static charges in the substrate 2 can be avoided. If a great number of static charges are residual on the substrate 2, the patterns on the substrate 2 will be damages and the accuracy of the subsequent processes will be lowered.

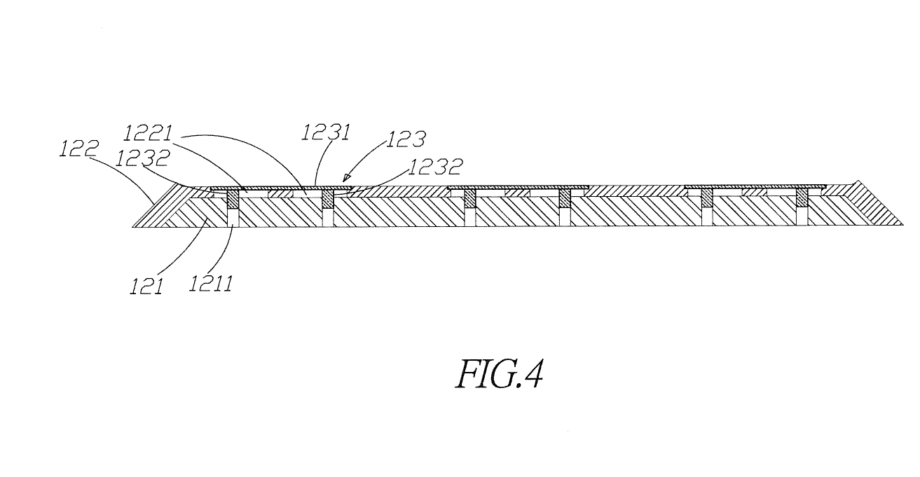

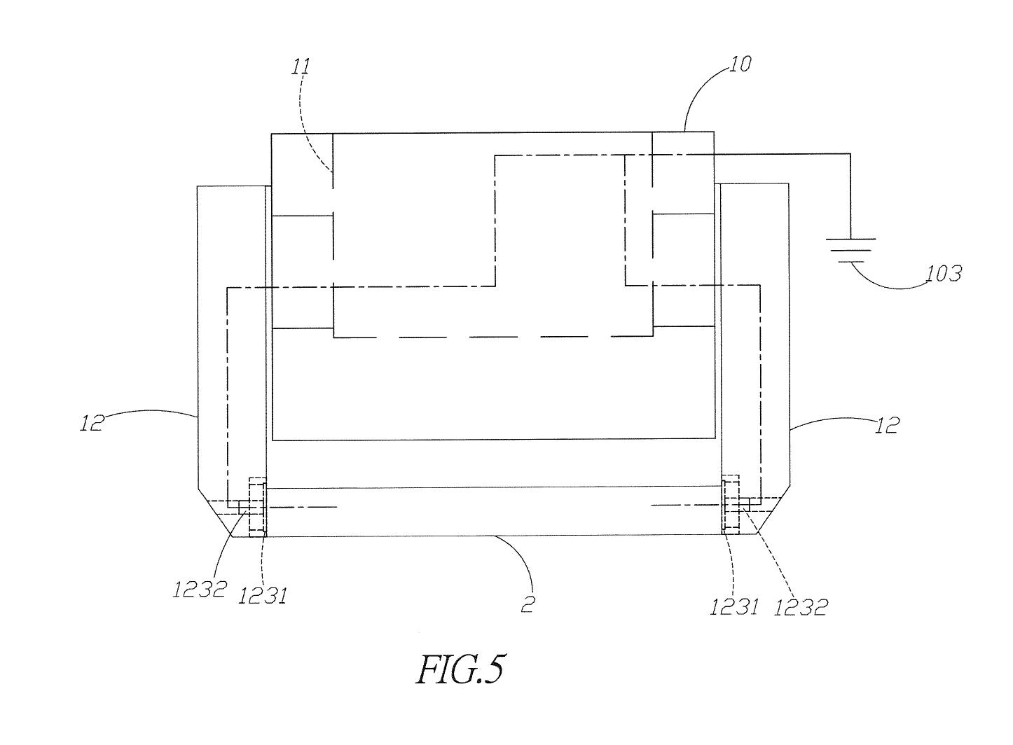

FIG. 4 shows a cross-sectional of the clipping member according to the second embodiment of the present invention; FIG. 5 shows a usage diagram of the chuck structure according to the second embodiment of the present invention. As shown in the figures, according to the embodiment described above, by disposing the plurality of holes 1221 on the contact surface between the clipping member 12 and the substrate 2, the residual static charges on the substrate 2 can be reduced. Each clipping member 12 according to the present embodiment further comprises a plurality of first static-charge lead-out members 123 disposed on the surface of the junction between the clipping member 12 and the substrate 2. As the clipping member 12 is against the substrate 2, the first static-charge lead-out member 123 is located between the clipping member 12 and the substrate 2 and contacts the substrate 2 for leading out the static charges residual on the substrate 2.

Each first static-charge lead-out member 123 according to the present embodiment comprises a first conductive sheet 1231 and a conductive projective part 1232. The conductive projective part 1232 is disposed on the conductive sheet 1231; the conductive sheet 1231 is disposed on the surface of the junction between the clipping member 12 and the substrate 2; the conductive projective part 1232 passes through the corresponding hole 1221 of the clipping member 12 and is connected with hole 1211 of the conductive base 121. The connecting structure between the conductive sheet 1231 and the conductive base 121 is only an embodiment. Alternatively, the conductive projective part 1232 can be disposed on the conductive base 121; the hole 1211 can be disposed at the conductive sheet 1231; and the conductive projective part 1232 disposed on the conductive base 121 passes through the hole 1211 of the conductive sheet 123 for connecting the conductive sheet 1231 with the conductive base 121. The details will not be described further.

When the clipping member 12 is against the substrate 2, the conductive sheet 1231 contacts the substrate 2. The static charges on the substrate 2 are transferred to the conductive sheet 1231. By means of the conductive projective part 1232, the conductive sheet 1231 transfers the static charges on the substrate 2 to the conductive base 121. Then the conductive base 121 transfers the static charges to a ground 103 of the conductive base 10. The static charges are led out from the ground 103, reducing the residual static charges on the substrate 2. Thereby, a great number of residual static charges on the substrate 2 can be avoided, which prevents damages in the substrate 2 caused by electrostatic discharge.

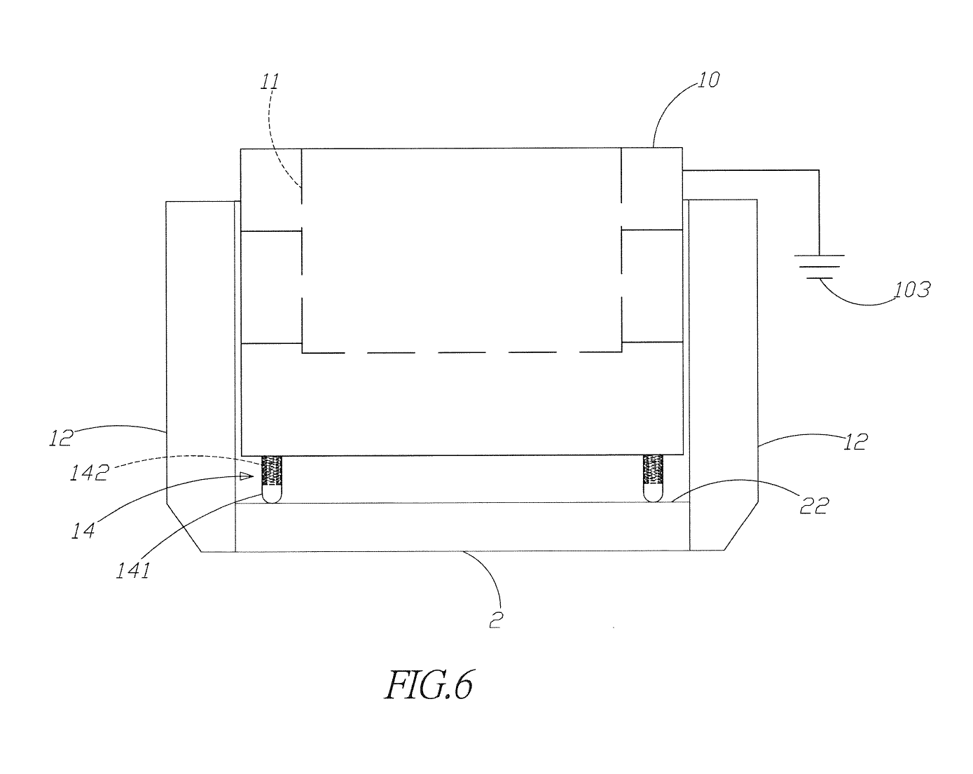

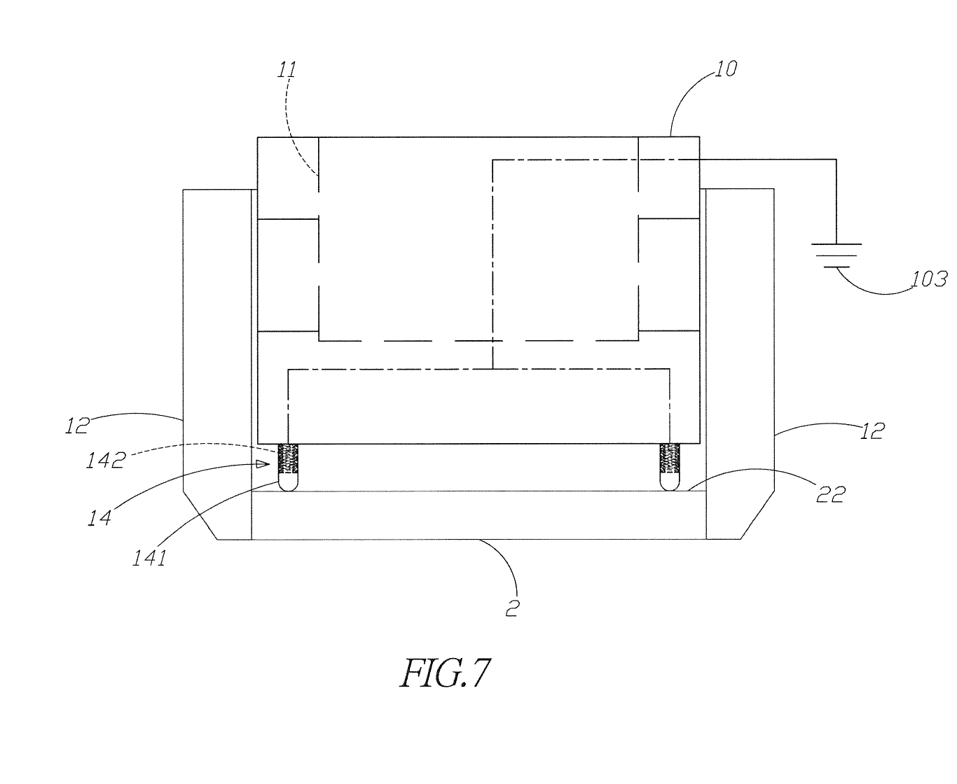

FIG. 6 and FIG. 7 shows a schematic diagram and a usage diagram of the chuck structure according to the third embodiment of the present invention. As shown in the figure, the chuck structure 1 according to the present embodiment further comprises at least a second static-charge lead-out member 14. The second static-charge lead-out member 14 is a supporting member, which is disposed on the surface facing the conductive base 10 of the substrate 2 for supporting the surface of the substrate 2 facing the conductive base 10. The second static-charge lead-out member 14 contacts the substrate 2. The supporting member 141 is a conductor for leading out the static charges on the substrate 2 to the ground 103 of the conductive base 10. Thereby, the residual static charges on the substrate 2 is reduced; the damages on the substrate 2 caused by electrostatic discharge can be thus prevented.

The second static-charge lead-out member 14 according to the present embodiment further comprises a conductive elastic member 142. One end of the conductive elastic member 142 is connected to the supporting member 141; the other end of the conductive elastic member 142 is connected to the conductive base 10. When the second static-charge lead-our member 14 is against the surface 22 of the substrate 2, the substrate 2 first presses the supporting member 141 and makes the supporting member 141 to move towards the conductive base 10. Then the conductive elastic member 142 between the supporting member 141 and the conductive base 10 starts to compress and generate a reacting force for pushing the supporting member 141 to move towards the surface of the substrate 2 and enabling the supporting member 141 to support the surface 22 of the substrate 2 firmly. Thereby, the contact between the second static-charge lead-out member 14 and the substrate 2 is ensured, so that the static charges on the substrate 2 can be led out.

The present invention provides a chuck structure for substrate cleansing equipment. The surface of the junction of the clipping member of the chuck structure and the substrate has the plurality of holes for reducing the contact area between the clipping member and the substrate and further reducing a great number of static charges generated due to the friction when the clipping member comes off the substrate. Besides, a great number of residual static charges on the substrate can be avoided. The surface of the junction of the clipping member and the substrate further has at least a first static-charge lead-out member; the surface of the conductive base facing the substrate further has at least a second static-charge lead-out member. The first static-charge lead-out member and the second static-charge lead-out member contact the substrate for leading the residual static charges on the substrate to the ground of the conductive base. Thereby, the quantity of the residual static charges on the substrate can be reduced substantially as well. The structures described above can prevent the electrostatic discharge damages on the substrate due to a great number of static charges. Hence, the precision of the patterns on the substrate can be maintained; the precision of the subsequent processes will not be affected.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A chuck structure for substrate cleansing equipment, comprising:
a conductive base; and
at least a pair of clipping members, disposed on both corresponding sides of said conductive base, respectively, each said clipping member having a plurality of hole on a surface thereof, said pair of clipping members clipping a substrate, and said surface having said plurality of holes against said substrate.

2. The chuck structure for substrate cleansing equipment of claim 1, wherein each said clipping member comprises:
a conductive base; and
a rubber strip, disposed at said conductive base, said plurality of holes passing through said rubber strip, and the surface of said rubber strip having said plurality of holes against said substrate.

3. The chuck structure for substrate cleansing equipment of claim 2, wherein each said clipping member further comprises at least a first static-charge lead-out member, disposed on the surface of said rubber strip against said substrate, and connected to said conductive base for leading the static charges on said substrate to a ground of said conductive base.

4. The chuck structure for substrate cleansing equipment of claim 3, wherein said first static-charge lead-out member comprises a conductive sheet, disposed on the surface of said rubber strip against said substrate and connected to said conductive base.

5. The chuck structure for substrate cleansing equipment of claim 3, wherein said first static-charge lead-out member comprises a plurality of conductive projective parts, disposed on said conductive sheet, passing through said corresponding holes, respectively, and connected with said conductive base.

6. The chuck structure for substrate cleansing equipment of claim 3, wherein said conductive base has a plurality of conductive projective parts passing through said corresponding holes, respectively, and connected with said conductive sheet.

7. The chuck structure for substrate cleansing equipment of claim 1, and further comprising at least a second static-charge lead-out member, disposed on said conductive base, and supporting said substrate for leading the static charges on said substrate to a ground of said conductive base.

8. The chuck structure for substrate cleansing equipment of claim 7, wherein said second static-charge lead-out member comprises a supporting member, disposed on said conductive base, and supporting said substrate.

9. The chuck structure for substrate cleansing equipment of claim 8, wherein said second static-charge lead-out member further comprises a conductive elastic member, having one end disposed at said supporting member, and having the other end connected to said conductive base for supporting said substrate.
